(19) United States
(12) Patent Application Publication
(10) Pub. No.: US 2007/0093038 A1
(43) Pub. Date: Apr. 26, 2007

(54) Method for making microchips and microchip made according to this method

(76) Inventor: Andreas Koenig, Dresden (DE)

Correspondence Address: SLATER & MATSIL LLP, 17950 PRESTON ROAD, SUITE 1000, DALLAS, TX, 75252, US

(21) Appl. No.: 11/259,750

(22) Filed: Oct. 26, 2005

(51) Int. Cl. H01L 21/00

(52) U.S. Cl. 438/460

(57) ABSTRACT

Microchips have a first surface and a second surface, which second surface is opposite the first surface. Microelectronic structures are fabricated at the first surface. At least two layers of lacquer are deposited on the second surface of the microchip; however, any two contiguous layers have different mechanical properties.

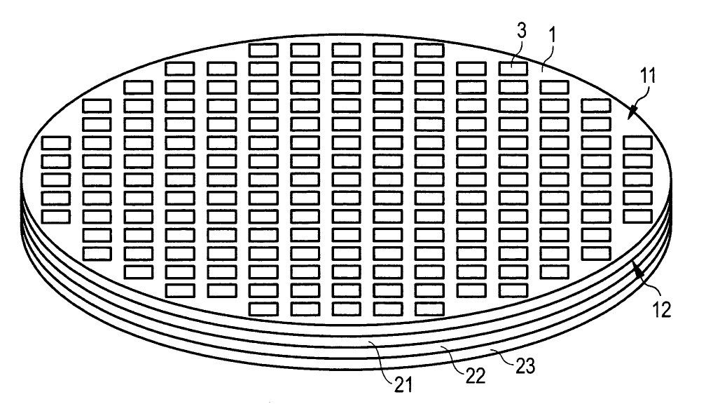

### TECHNICAL FIELD

The present invention relates to a method for making microchips and a microchip made according to this method.

### BACKGROUND

In the making of integrated circuits (ICs), microelectronic structures, which function as active electronic elements, e.g., as transistors, are created on a surface of a silicon disc, the so-called wafer, according to techniques known in the art. During this process, on each wafer the structures needed for a multitude of single integrated circuits (also called “microchips” hereinafter) are produced. Following a functional test, the integrated circuits thus obtained are separated by sawing the wafer to pieces.

Following their separation, the microchips are connected to a wiring board and a protective cap, or housing, is molded atop the microchip. An electronic device thus produced may contain a single microchip or comprise multiple microchips, which form a so-called multi-chip package. The electric terminals of the microchip are electrically connected to the pins of the housing.

Wafers are produced by sawing a silicon single crystal into thin disks with a thickness ranging from between 0.5 and 1.5 millimeters. Following the establishment of the microelectronic structures on a first surface of the wafer, its thickness is reduced in a grinding process, the final thickness typically ranging from about 30 to 100 micrometers. Two principal types of grinding processes are utilized for the thinning of wafers.

In the “grinding before dicing” process, the wafer is first thinned by grinding its second surface, or back surface (i.e., the surface that is free from microelectronic structures) and then sawn to pieces (the future microchips). During grinding, the first surface, or front surface (i.e., the surface that carries the microelectronic structures) is protected by an adhesive tape, while during sawing, the second surface is protected by such adhesive tape, the sawing process being conducted from the first to the second surface of the wafer.

In the “dicing before grinding” process, the wafer is first sawn from the first to the second surface, the depth of the saw kerf being less than the thickness of the wafer. Consequently, the microchips are not separated in this process. Rather, the wafer remains a contiguous disk. Only after finishing the sawing, the second surface of the wafer is thinned in a grinding process in which the remaining material between the future microchips is removed and thus, the microchips are separated. The respective surfaces of the wafer are protected by adhesive tapes as has been described above.

The protective tapes attached for the protection of the wafer usually have a thickness, which may be several times greater than the thickness of the thinned wafer. Therefore, when the wafer is to be removed from the chuck of the processing apparatus or the separated microchips are to be detached from the protective tape, deformation of the wafer or the microchips, respectively, occurs. Such deformation induces considerable stress in the wafer or microchip, which can lead to defects in the crystalline structure of the semiconductor substrate. The deformation and the resulting stress conditions and defects can lead to severe problems during the subsequent process steps, like molding or bonding, and, at worst, even cause fracture of the wafer or microchip.

Another problem is that, during the separation of the microchips in the sawing process, the danger of chipping, i.e., the breaking out of small particles off the boundary region of the microchips, increases with decreasing thickness of the wafer. Through this, the microchips may be damaged beyond serviceability.

Finally, the microchips are also at risk from deformations, which are generated by thermal loads during the assembly of the microchip and the wiring board and the bonding process.

In order to prevent deformation (warpage, strain) and consequent damage to the microchips during their manufacture, several approaches have been proposed in the past.

From U.S. Pat. No. 6,815,234 B2, which is incorporated herein by reference, it is known to apply a single stress compensating layer to the back surface of semiconductor chips. Materials proposed include dielectric materials like silicon nitride and silicon oxide. The possibility to use non-dielectric materials, like metals, is mentioned as well.

In contrast, U.S. Pat. No. 6,724,967 B2, which is incorporated herein by reference, discloses the application of one single stress compensating layer of silica on each surface of the microchip.

In U.S. Patent Application Publication Nos. 2005/0085008 A1 and 2005/0095812 A1, which are both incorporated herein by reference, single layers of several materials are applied to the back side of a chip, the multitude of proposed materials exclusively comprising of polymers, like epoxies, acrylics, silicones, urethanes, siloxanes, Parylene or two-part epoxy.

U.S. Patent Application Publication No. 2004/0224442 A1, which is incorporated herein by reference, discloses stereolithographically produced stiffeners, which are attached to a semiconductor device in order to prevent deformation. The stiffeners may be composed of a plurality of layers. They may be fabricated from a dielectric material, such as a dielectric photoimageable polymer. During the stereolithographic process, the layers are given a predetermined topography.

However, none of the proposed techniques offers a satisfactory solution to the problems discussed above.

### SUMMARY OF THE INVENTION

In various embodiments, the present invention relates to a method for making microchips, which employs a “grinding before dicing” process, and a microchip made according to this method.

In a first aspect, the present invention provides a method for making microchips and microchips made according to that method, which effectively solve the aforementioned problems at little extra cost. In another aspect, the invention provides a microchip that is less sensitive to external mechanical or thermal loads than conventional microchips, yet exhibits a low profile, i.e., remains comparatively thin, thus allowing for low profile devices even if stacked in multi-chip packages.

In a first embodiment, microchips are made by fabricating microelectronic structures in the first surface of a wafer. A first protective tape is attached to the first surface of the wafer. The wafer is thinned to a predetermined value of thickness by grinding the second surface of the wafer. A second protective tape is attached to the second surface of the wafer. The first protective tape is detached from the first surface of the wafer. The microchips are separated by sawing the wafer. The sawing process progresses from the first surface towards the second surface of the wafer. Prior to the step of attaching the second protective tape to the second surface of the wafer, at least two layers of lacquer are applied to and cured on the second surface of the wafer. Any two contiguous layers are executed so as to have different mechanical properties.

The microchips produced according to this method have a first surface and a second surface. which second surface is opposite the first surface, and, as is usual, have microelectronic structures on their first surface. At least two layers of lacquer are deposited on the second surface of the microchip; however, any two contiguous layers have different mechanical properties.

The microchips are less sensitive to external mechanical and thermal loads compared to conventional microchips. The at least two layers of lacquer can be selected and dimensioned such that a microchip with a desired stiffness, i.e., resistance against deformation, can be obtained depending on the anticipated operational load, i.e., mechanical or thermal loads expected to occur during the life cycle of the microchips. In particular, the selection of the mechanical properties of the layers as defined by the properties of the lacquer itself and the thickness of the layer, makes it possible that the microchip withstands the operational load substantially without deformation.

The method disclosed herein allows for a competitive and cost-effective production of highly reliable microchips, i.e., microchips that are highly insensitive to mechanical or thermal loads, as for instance to stress-induced warpage, bending or other forms of deformation. Moreover, chipping of the substrate, i.e., the breakout of small particles from the edges, which is an issue during the separation of the microchips from the wafer, is significantly reduced.

The microchips according to the invention can be produced at little extra cost. They withstand mechanical or thermal loads and, due to the thinness of the layers, can be used in multi-chip packages in which a plurality of microchips is stacked to form a single microelectronic device.

### BRIEF DESCRIPTION OF THE DRAWING

With reference to the drawing, the invention is now described in more detail. The figure shows the principal configuration of a wafer, which contains a plurality of future microchips according to the invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Referring to the figure, a semiconductor wafer 1 has been prepared for separation. In this wafer, microelectronic structures for a plurality of prospective microchips 3 have been fabricated on a first surface 11 of the wafer 1. This fabrication uses any microelectronic fabrication technique and can form devices such as memory devices or logic devices, for example.

To separate the microchips 3, a first protective tape (not shown) has been attached to the first surface 11 of the wafer 1 and the wafer 1 has been thinned to a predetermined value of thickness by grinding the second surface 12 of the wafer 1.

Three layers of lacquer or other material 21, 22, 23 have been applied to and cured on the second surface 12 of the wafer 1. Any two contiguous layers 21, 22, 23 are executed so as to have different mechanical properties, e.g., the first and third layers 21, 23 are relatively tough while the second layer 22 is relatively soft. Mechanical properties, as used herein, include the toughness (e.g., stiffness, hardness and/or elasticitity) of a solid, elastic body such as a semiconductor substrate, a layer of lacquer or a compound of a substrate and one or more layers of lacquer. These properties include bending stiffness or the deformation resistance, as effected by the material's Young's modulus, its thickness or cross-sectional area and so forth.

In one embodiment, the first and third layers 21 and 23 are made from the same material so that they have the same Young's modulus. In another embodiment, the materials of the first and third layers 21 and 23 can be different but the Young's modulus the same or close to the same relative to the Young's modulus of the second layer 22. The thickness of the first layer 21, i.e., the one that has been applied directly to the second surface 12 in the figure, is selected so that the compound constituted by the substrate and the first layer 21 has the same bending stiffness as the third layer 23. The second layer 22, which is made of a relatively soft material, e.g., a lacquer of comparatively low Young's modulus, transmits forces induced by mechanical or thermal load between the first and third layers 21 and 23.

In another embodiment, it is beneficial to apply a first layer 21 of a lacquer with a relatively low value of Young's modulus (leading to low toughness, i.e., great deformability) and to cover this first layer 21 with a second layer 22 of a lacquer with a relatively high value of Young's modulus (high toughness, i.e., little deformability). The lacquer of low toughness serves to compensate stress while the lacquer of low toughness is selected with respect to its toughness and the thickness of the layer so as to react to applied stress in the same manner as the microchip. Thus, a stress, which would normally lead to a deformation of the microchip, will be compensated so that the microchip does not warp or otherwise deform.

It has been found that an uneven number of layers of lacquer is particularly beneficial. For example, a configuration, which compensates stress even better and minimizes deformation of the microchip 3 can be achieved by applying three layers of lacquer 21, 22, 23, as shown in the example of the figure. Preferably the first and third layers 21 and 23 are of relatively high toughness while the second layer 22, which is placed between the first and third layers 21 and 23, is of relatively low toughness.

The first layer 21 reinforces the microchip 3 and the third layer 23 compensates the substrates attempts to deform under stress. The second layer 22 acts as a transmitter between the first and third layers 21 and 23, through which stress and forces are transferred, which build up in the substrate of microchip 3 and the first and third layers of lacquer, respectively. The configuration of the layers can, of course, comprise more than three layers, uneven numbers being clearly preferred. As a result, it is particularly beneficial to provide three, five, seven or more layers of lacquer, although it has to be taken into account that the expenditure needed to make such a configuration in terms of time and production cost will increase with the number of layers to be produced. On the other hand, inevitable deviation of the actual thickness of a layer from the desired value will be easier compensated with a greater number of layers. Also, there may be applications in which configurations comprising an even number of layers are favorable.

It is possible to provide for a good compensation of stress if two layers, which are not directly linked to each other, i.e., two layers enclosing a third, intermediary layer, are of the same toughness, i.e., if they are of the same thickness and the same Young's modulus. In this case, the two layers of like mechanical properties can be made of the same lacquer, which results in low cost of production. This way, a configuration of for example three layers of lacquer can be made from only two different sorts of lacquer.

Taking into account the toughness of the semiconductor substrate itself it can be necessary or desirable to produce two layers not adjacent to each other, e.g., a first and a third layer, so as to be different in thickness in order to obtain the same stiffness or toughness in the compound constituted by the substrate and the first layer as in the third layer, the second layer in-between the first and the third layer serving as a stress compensating layer.

As for the lacquer, several types of materials can be used for the purpose of making a configuration according to embodiments of the invention. It has been found, however, that it is beneficial to select lacquers from out of the group of polymer or silicone lacquers.

Following the application and cure of the layers of lacquer 21, 22, 23, the microchips 3 can be separated by attaching a second protective tape (not shown) to the second surface 12 of the wafer 1 and detaching the first protective tape (not shown) from the first surface 11 of the wafer 1. Finally, the wafer 1 can be sawed from the first surface 11 towards the second surface 12 of the wafer 1 to obtain microchips 3.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is, therefore, intended that the appended claims encompass any such modifications or embodiments.

What is claimed is:

1. A method for making microchips, the method comprising:
providing a wafer with a first surface and a second surface, the second surface opposite the first surface;
fabricating microelectronic structures at the first surface of the wafer;
attaching a first protective tape to the first surface of the wafer;
thinning the wafer to a predetermined value of thickness by grinding the second surface of the wafer;
applying and curing at least two layers of lacquer on the second surface of the wafer, wherein the at least two layers of lacquer have different mechanical properties;
attaching a second protective tape to the second surface of the wafer;
detaching the first protective tape from the first surface of the wafer; and
separating microchips by sawing the wafer, the sawing process progressing from the first surface towards the second surface of the wafer.

2. The method of claim 1, wherein applying the at least two layers of lacquer comprises applying an odd number of layers to the second surface of the wafer.

3. The method of claim 2, wherein the at least two layers of lacquer physically not touching each other have substantially the same mechanical properties.

4. The method of claim 2, wherein the at least two layers of lacquer not physically touching each other have substantially the same Young's modulus.

5. The method of claim 2, wherein the at least two layers of lacquer not physically touching each other have substantially the same thickness.

6. The method of claim 2, wherein a first layer of lacquer is applied directly to the wafer and a material of the wafer have substantially the same mechanical properties as another layer of lacquer not physically touching the first layer of lacquer.

7. The method of claim 1, wherein applying the at least two layers of lacquer comprises applying at least one layer of a silicone lacquer.

8. The method of claim 1, wherein applying the at least two layers of lacquer comprises applying at least one layer of a polymer lacquer.

9. A microchip comprising:
a semiconductor substrate having a first surface and a second surface, said second surface opposite said first surface;
microelectronic structures disposed at the first surface of the microchip; and
at least two layers of lacquer disposed on the second surface of the microchip, wherein the at least two layers of lacquer have different mechanical properties.

10. The microchip of claim 9, wherein the at least two layers of lacquer comprise an odd number of layers of lacquer.

11. The microchip of claim 10, wherein at least two of the layers of lacquer that are not physically contacting each other have substantially the same mechanical properties.

12. The microchip of claim 11, wherein at least two of the layers of lacquer that are not physically contacting each other have substantially the same Young's modulus.

13. The microchip of claim 10, wherein at least two of the layers of lacquer that are not physically contacting each other have substantially the same thickness.

14. The microchip of claim 9, wherein a first layer of lacquer that is applied directly to the semiconductor substrate is produced so that a material of the substrate and the first layer of lacquer have substantially the same mechanical properties as another layer of lacquer not physically contacting said first layer of lacquer.

15. The microchip of claim 9, wherein at least one layer of lacquer comprises a silicone lacquer.

16. The microchip of claim 9, wherein at least one layer of lacquer comprises a polymer lacquer.

17. The microchip of claim 9, wherein the at least two layers of lacquer comprise:
a first layer of lacquer contacting the second surface of the semiconductor wafer, the first layer of lacquer having a first Young's modulus;
a second layer of lacquer contacting the first layer of lacquer, the second layer of lacquer having a second Young's modulus that is less than the first Young's modulus; and
a third layer of lacquer contacting the second layer of lacquer, the third layer of lacquer having a third Young's modulus that is greater than the second Young's modulus.

18. The microchip of claim 17, wherein the first Young's modulus is substantially equal to the third Young's modulus.

19. The microchip of claim 17, wherein the first layer of lacquer and the third layer of lacquer comprise the same material.

20. A method of making a semiconductor device, the method comprising:
providing a semiconductor wafer;
fabricating microelectronic structures at a first surface of the semiconductor wafer;
thinning the semiconductor wafer from a second surface that is opposite the first surface;
forming a first layer of lacquer over the second surface of the semiconductor wafer, the first layer of lacquer having a first Young's modulus;
forming a second layer of lacquer over the first layer of lacquer, the second layer of lacquer having a second Young's modulus that is less than the first Young's modulus;
forming a third layer of lacquer over the second layer of lacquer, the third layer of lacquer having a third Young's modulus that is greater than the first Young's modulus; and
singulating the wafer into a plurality of microchips.

21. The method of claim 20, wherein the first Young's modulus is substantially equal to the third Young's modulus.

22. The method of claim 20, wherein the first layer of lacquer and the third layer of lacquer comprise the same material.

23. The method of claim 20, wherein the first layer of lacquer physically contacts the second surface of the semiconductor wafer, the second layer of lacquer physically contacts the first layer of lacquer, and the third layer of lacquer physically contacts the second layer of lacquer.

24. The method of claim 20, wherein at least one of the first, second or third layers of lacquer comprises a silicone lacquer.

25. The method of claim 20, wherein at least one of the first, second or third layers of lacquer comprises a polymer lacquer.
